(19) United States
(12) Patent Application Publication
(10) Pub. No.: US 2010/0240209 A1
(43) Pub. Date: Sep. 23, 2010

(54) SEMICONDUCTOR DEVICES INCLUDING HYDROGEN IMPLANTATION LAYERS AND METHODS OF FORMING THE SAME

(76) Inventors: Jae-Hun Jeong, Gyeonggi-do (KR); Ki-Nam Kim, Seoul (KR); Soon-Moon Jung, Gyeonggi-do (KR); Jae-Hoon Jang, Gyeonggi-do (KR)

Correspondence Address: MYERS BIGEL SIBLEY & SAJOVEC, PO BOX 37428, RALEIGH, NC, 27627, US

(21) Appl. No.: 12/792,912

(22) Filed: Jun. 3, 2010

Related U.S. Application Data
(62) Division of application No. 12/045,803, filed on Mar. 11, 2008.

(30) Foreign Application Priority Data
Mar. 12, 2007 (KR) 10-2007-0024092

(51) Int. Cl. H01L 21/28

(52) U.S. Cl. 438/591; 257/E21.21

(57) ABSTRACT

Provided are semiconductor devices and methods of forming the same. The semiconductor devices include a substrate further including a hydrogen implantation layer and a gate structure formed on the hydrogen implantation layer to include a first insulating layer, a charge storage layer, a second insulating layer and a conductive layer.

### CROSS-REFERENCE TO RELATED APPLICATION

This application is a divisional of U.S. patent application Ser. No. 12/045,803; filed Mar. 11, 2008, which claims priority under 35 USC §119 to Korean Patent Application No. 10-2007-0024092, filed on Mar. 12, 2007, the disclosure of which is incorporated herein by reference in its entirety.

### FIELD OF THE INVENTION

The present invention relates to semiconductor devices, and more particularly, to semiconductor devices including a hydrogen implantation layer and methods of forming the same.

### BACKGROUND OF THE INVENTION

Semiconductor memory devices may be classified into volatile semiconductor memory devices and non-volatile semiconductor memory devices. The volatile semiconductor memory devices generally lose their stored data when the power supply is interrupted. In contrast, non-volatile semiconductor memory devices generally retain their stored data when the power supply is interrupted.

A cell transistor of a non-volatile semiconductor memory device may include a charge storage layer for data storage. A tunneling insulating layer may be disposed between the charge storage layer and a substrate, and program and erase operations of the cell transistor may be performed by Fowler-Nordheim (FN) tunneling. During program operation, charges in the substrate generally pass through the tunneling insulating layer by the FN tunneling and are stored in the charge storage layer. As a result, the cell transistor is turned off. During the erase operation, charges in the charge storage layer generally pass through the tunneling insulating layer by FN tunneling and are injected into the substrate. As a result, the cell transistor is turned on. As program and erase operations are repeatedly performed, the charges are repeatedly passed through the tunneling insulating layer. Consequently, an interface between the substrate and the tunneling insulating layer is damaged. That is, a silicon-hydrogen bond located at the interface is dissociated and a dangling bond may be formed at the interface by the charges. The dangling bond may function as an interface trap to change a threshold voltage of the cell transistor. A characteristic of a programmed cell transistor and data stored in the cell transistor may be changed by the threshold voltage variation. Thus, the reliability of a semiconductor device may be degraded.

### SUMMARY OF THE INVENTION

Embodiments of the present invention provide methods of forming a semiconductor device including implanting hydrogen ions into a substrate to form a hydrogen implantation layer in a surface of the substrate, and forming a gate structure including a first insulating layer, a charge storage layer, a second insulating layer and a conductive layer stacked sequentially on the hydrogen implantation layer. In some embodiments, the hydrogen implantation layer includes silicon-hydrogen bonds and hydrogen ions that are not bonded to silicon, and wherein the number of hydrogen ions that are not bonded to silicon is greater than the number of the silicon-hydrogen bonds present in the hydrogen implantation layer. In some other embodiments, the hydrogen implantation layer includes dangling bonds generated by dissociation of the silicon-hydrogen bonds, and wherein the hydrogen ions that are not bonded to silicon can subsequently bond to a silicon-containing compound having the dangling bonds.

Embodiments of the present invention further provide methods of forming a semiconductor device including implanting hydrogen ions into a first substrate to form a hydrogen implantation layer to a predetermined depth of the first substrate; dividing the hydrogen implantation layer to form a sub-substrate including a divided hydrogen implantation layer on a surface of the sub-substrate; and forming a gate structure including a first insulating layer, a charge storage layer, a second insulating layer and a conductive layer stacked sequentially on the divided hydrogen implantation layer. In some embodiments, the substrate and/or the sub-substrate resulting from division thereof includes silicon-hydrogen bonds and hydrogen ions that are not bonded to silicon, and wherein the number of hydrogen ions that are not bonded to silicon is greater than the number of the silicon-hydrogen bonds present in the hydrogen implantation layer.

Additionally, embodiments of the present invention provide semiconductor devices including a hydrogen implantation layer in a surface of a substrate; and a gate structure including a first insulating layer, a charge storage layer, a second insulating layer and a conductive layer stacked sequentially on the hydrogen implantation layer.

### BRIEF DESCRIPTION OF THE FIGURES

The accompanying figures are included to provide a further understanding of the present invention. More specifically, the above and other features and advantages of the present invention will become more apparent by describing in detailed embodiments thereof with reference to the accompanying drawings, in which:

FIG. 1 is a cross sectional view of a semiconductor device according to some embodiments of the present invention.

FIGS. 2a and 2b are cross sectional views illustrating a method of forming a semiconductor device in accordance with some embodiments of the present invention.

FIGS. 3a through 3e are cross sectional views illustrating a method of forming a semiconductor device in accordance with some embodiments of the present invention.

FIG. 4 is a graph showing an operation characteristic of a semiconductor device in accordance with some embodiments of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. All publications, patent applications, patents, and other references mentioned herein are incorporated by reference in their entirety.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

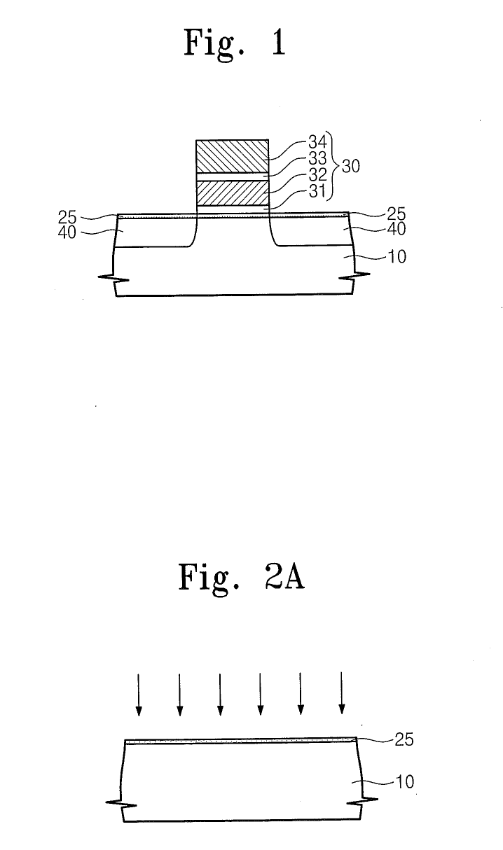

Referring to FIG. 1, a semiconductor device according to some embodiments of the present invention will be described. Specifically, the semiconductor device includes a hydrogen implantation layer 25 formed on a surface of a substrate 10. The substrate 10 may be a semiconductor substrate such as a single crystalline silicon substrate or a silicon on insulator (SOI) substrate. The hydrogen implantation layer 25 may be formed to include a hydrogen concentration of about 10¹⁴ to 10¹⁷/cm². The hydrogen implantation layer 25 may include a silicon-hydrogen bond formation. An exemplary silicon-hydrogen bond formation is shown below as formula 1:

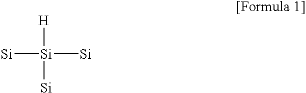

Alternatively, the hydrogen implantation layer 25 may include hydrogen that is not bonded to silicon. The hydrogen implantation layer 25 may include a number of hydrogen ions that are not bonded to silicon, which may be greater than the number of the silicon-hydrogen bonds. The hydrogen implantation layer 25 may include a dangling bond, which accordingly, is not bonded as shown in formula 2. The dangling bond may be generated by dissociation of the silicon-hydrogen bond.

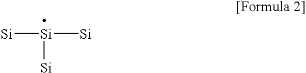

A hydrogen ion that is not bonded may bond to the dangling bond and the silicon-hydrogen bond present in the structure shown in formula 1 may be formed.

Further referring to FIG. 1, a gate structure 30 may be disposed on the hydrogen implantation layer 25. The gate structure 30 may include a first insulating layer 31, a charge storage layer 32, a second insulating layer 33 and a conductive layer 34 that are sequentially stacked.

Impurity regions 40 may be disposed in the substrate of both sides of the gate structure 30. The impurity regions may be source/drain regions. A cell transistor of a non-volatile memory device may include the gate structure 30 and/or the impurity regions 40.

The non-volatile memory device may include a floating gate type device and a charge trap type device. In the case of the floating gate type device, the charge storage layer 32 may include conductive material, and the first insulating layer 31, the charge storage layer 32, the second insulating layer 33 and the conductive layer 34 may correspond to a gate insulating layer, a floating gate, intergate insulating layer and control gate, respectively. In the case of the charge trap type device, the charge storage layer 32 may include conductive material, and the first insulating layer 31, the charge storage layer 32, the second insulating layer 33 and the conductive layer 34 may correspond to a tunneling insulating layer, a charge trap layer, a blocking insulating layer and a control gate, respectively. The semiconductor device according to some embodiments of the present invention may be applied to a non-volatile memory device in addition to the floating gate type device and the charge trap type device. A patterned shape of the gate structure 30 may be changed according to the type of the non-volatile memory device. Thus, the shape of the gate structure 30 according to some embodiments of the present invention is not limited to the shape shown in FIG. 1.

Program and erase operations of the non-volatile memory device may be performed by a Fowler-Nordheim (FN) tunneling. During program operation, charges in the substrate 10 may pass through the first insulating layer 31 by FN tunneling and are stored in the charge storage layer 32. As a result, a threshold voltage of the cell transistor may increase and the cell transistor may be turned off. During erase operation, charges in the charge storage layer 32 may pass through the first insulating layer 31 by the FN tunneling and be injected into the substrate 10. As a result, a threshold voltage of the cell transistor may decrease and the cell transistor may be turned on.

As program and erase operations are repeatedly performed, the charges may be repeatedly passed through the tunneling insulating layer. Consequently, an interface between the substrate and the tunneling insulating layer may be damaged. As described above, a silicon-hydrogen bond located at the interface may be dissociated by the charges and a dangling bond, which may act as an interface trap, may be formed at the interface. However, since the semiconductor device according to some embodiments of the present invention may include a number of hydrogen ions that are not bonded at the interface, the dangling bonds may react with the free hydrogen ions to form silicon-hydrogen bonds again. Accordingly, the number of dangling bonds that may act as an interface trap may be minimized, and the threshold voltage of the cell transistor may maintain a specific value with minimal change, if any.

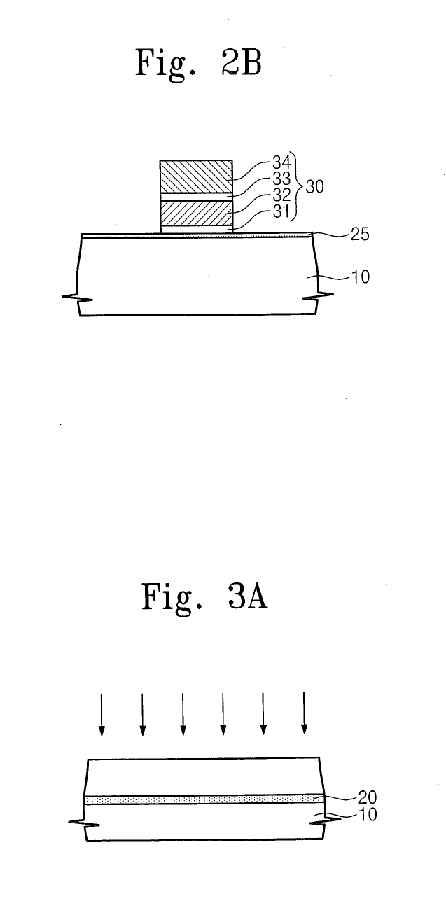

Referring to FIGS. 2a and 2b, a method of forming a semiconductor device according to some embodiments of the present invention will be described.

Referring to FIG. 2a, hydrogen ions may be implanted into a substrate 10 to form a hydrogen implantation layer 25. A semiconductor substrate such as a single crystalline silicon substrate or a silicon on insulator (SOI) substrate may be used as the substrate 10. The hydrogen ions may have a concentration of about 10¹⁴ to 10¹⁷/cm² and may be implanted to a depth of about 1000 angstroms or less. A portion of the implanted hydrogen ions may bond to silicon atoms on the surface of the substrate 10 to form silicon-hydrogen bonds and the remainder of the implanted hydrogen ions may be distributed in the hydrogen implantation layer 25 as hydrogen ions that are not bonded to silicon atoms. The number of free hydrogen that is not bonded to silicon may be greater than that of the silicon-hydrogen bond formations.

Referring to FIG. 2b, a gate structure 30 is formed on the hydrogen implantation layer 25 to include a first insulating layer 31, a charge storage layer 32, a second insulating layer 33 and a conductive layer 34. The first insulating layer 31 may be a silicon oxide layer. The silicon oxide layer may be formed by a thermal oxidation process. The charge storage layer 32 may be formed of a conductive material such as doped polysilicon or metal, or an insulating material such as a silicon nitride layer. The second insulating layer 33 may be formed of an oxide-nitride-oxide (ONO) layer or a high dielectric layer. The conductive layer 34 may be formed of doped polysilicon and/or metal.

Referring to FIG. 1 again, an ion implantation process is performed to form impurity regions 40 in the substrate 10 on both sides of the gate structure 30.

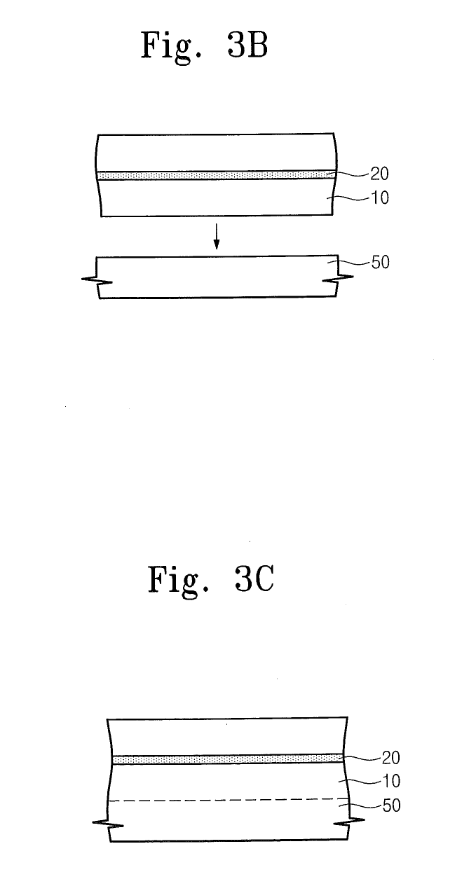

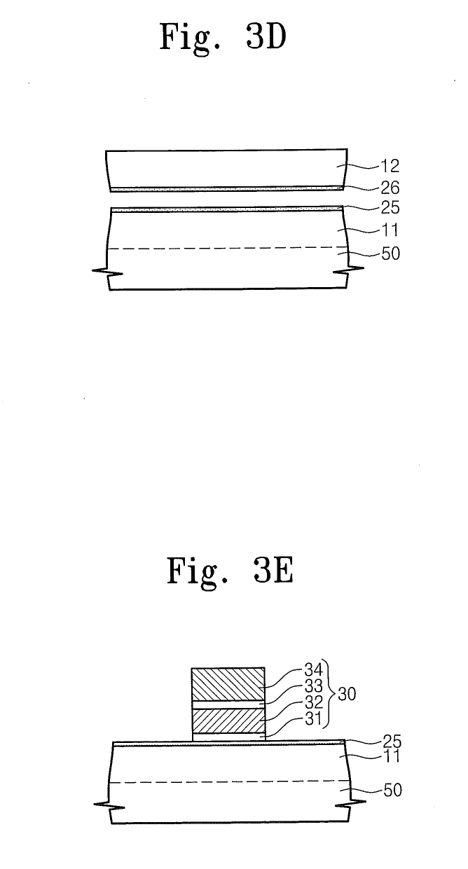

Referring to FIGS. 3a through 3e, a method of forming a semiconductor device according to further embodiments of the present invention will be described.

Referring to FIG. 3a, hydrogen ions may be implanted into a first substrate 10 to form a hydrogen implantation layer 20 to a predetermined depth of the substrate 10. The hydrogen ions may be implanted to have a concentration of about 10¹⁶ to 10¹⁷ ions/cm². A portion of the implanted hydrogen ions may bond to silicon atoms in the hydrogen implantation layer 20 to form silicon-hydrogen bonds and the remainder of the implanted hydrogen ions may be distributed in the hydrogen implantation layer 20 as free hydrogen ions that are not bonded to silicon atoms. The number of hydrogens that are not bonded may be greater than that of the hydrogens involved in the silicon-hydrogen bond formations.

Referring to FIGS. 3b and 3c, the first substrate 10 may be bonded to a second substrate 50. A buffer layer (not shown) may be formed between the first and second substrates 10 and 50. The buffer layer may be formed of an oxide layer.

Referring to FIG. 3d, the first substrate 10 is divided into two substrates 11 and 12 by cutting the hydrogen implantation layer 20. The hydrogen implantation layer 20 may also be divided into two hydrogen implantation layers 25 and 26. The hydrogen implantation layer 25 may be formed on a divided side of the substrate 11. The hydrogen implantation layer 26 may be formed on a divided side of the substrate 12. The two substrates 11 and 12 may be used as the substrate of the semiconductor device according to some embodiments of the present invention.

Referring to FIG. 3e, a planarization process is performed to planarize a surface of the hydrogen implantation layer 25. Roughness on the surface of the hydrogen implantation layer 25 generated when the hydrogen implantation layer 20 is divided may be minimized or removed by the planarization process. The degree of thickness of the surface of the hydrogen implantation layer 25 removed by performing the planarization process is about 1000 angstroms. Thus, it may be desirable that the range of the implantation process for forming the hydrogen implantation layer 25 is about 1000 to 7000 angstroms.

A gate structure 30 may be formed on the hydrogen implantation layer 25 to include a first insulating layer 31, a charge storage layer 32, a second insulating layer 33 and a conductive layer 34. The gate structure 30 may be formed using the same method as the embodiment described above.

Referring to FIG. 1 again, an ion implantation process is performed to form impurity regions 40 in the substrate 10 of both sides of the gate structure 30.

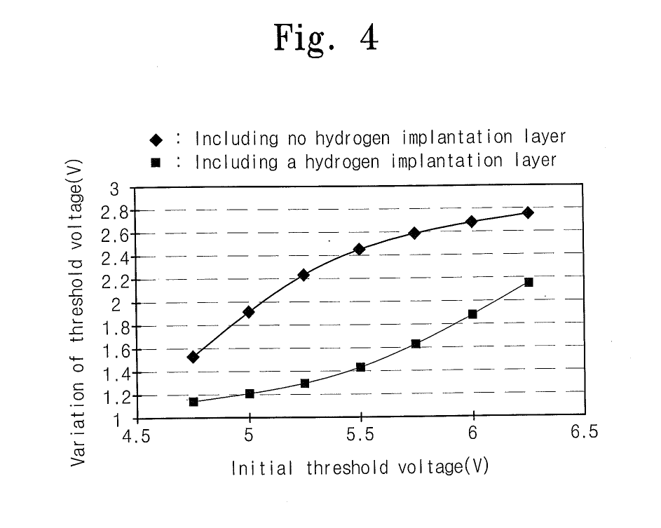

Referring to FIG. 4, an operation characteristic of the semiconductor device according to some embodiments of the present invention will be described. FIG. 4 shows operation characteristics when a substrate includes a hydrogen implantation layer and when a substrate does not include a hydrogen implantation layer, respectively. In FIG. 4, the horizontal axis shows an initial threshold voltage of a cell transistor and the vertical axis shows a variation of the threshold voltage when the cell transistor is stored at a temperature of 250° C. for two hours after an endurance test with 1200 cycles of program and erase operations.

As shown in FIG. 4, the variation of threshold voltage of a semiconductor device including a hydrogen implantation layer is less than the variation of threshold voltage of a semiconductor device that does not include a hydrogen implantation layer. That is, even though a semiconductor device including a hydrogen implantation layer performs program and erase operations repeatedly over a period of time, it may maintain an operation characteristic constantly. Therefore, a semiconductor device including a hydrogen implantation layer as described herein may have an improved reliability compared to a conventional semiconductor device that does not include a hydrogen implantation layer.

The above-disclosed subject matter is to be considered illustrative and exemplary, and not restrictive, and the appended claims are intended to cover all such modifications, enhancements, and other embodiments, which fall within the true spirit and scope of the present invention.

What is claimed is:

1. A method of forming a semiconductor device comprising:
implanting hydrogen ions into a first substrate to form a hydrogen implantation layer to a predetermined depth of the first substrate;
dividing the hydrogen implantation layer to form a second substrate comprising a divided hydrogen implantation layer on a surface of the second substrate; and
forming a gate structure comprising a first insulating layer, a charge storage layer, a second insulating layer and a conductive layer stacked sequentially on the divided hydrogen implantation layer.

2. The method of claim 1, wherein the hydrogen ions are implanted at a concentration of about 10¹⁶ to 10¹⁷ ions/cm².

3. The method of claim 1, wherein the hydrogen ions are implanted to a depth of about 1000 to 7000 angstroms.

4. The method of claim 1, wherein forming the second substrate comprises planarizing the divided hydrogen implantation layer.

5. The method of claim 1, further comprising bonding the first substrate to an additional substrate before dividing the hydrogen implantation layer.

6. The method of claim 1, wherein the hydrogen implantation layer comprises silicon-hydrogen bonds and hydrogen ions that are not bonded to silicon, and wherein the number of hydrogen ions that are not bonded to silicon is greater than the number of the silicon-hydrogen bonds present in the hydrogen implantation layer.

7. The method of claim 6, wherein the hydrogen implantation layer comprises dangling bonds generated by dissociation of the silicon-hydrogen bonds, and wherein the hydrogen ions that are not bonded to silicon can subsequently bond to a silicon-containing compound having the dangling bonds.
